(19) United States
(12) Patent Application Publication
(10) Pub. No.: US 2010/0040964 A1
(43) Pub. Date: Feb. 18, 2010

(54) EXPOSURE APPARATUS, EXPOSURE METHOD AND METHOD OF MANUFACTURING DISPLAY PANEL SUBSTRATE

(75) Inventors: RYOUJI NEMOTO, Kodama-gun (JP); Tomoaki Hayashi, Kodama-gun (JP); Satoshi Uehara, Kodama-gun (JP); Mitsuyoshi Koizumi, Kodama-gun (JP)

Correspondence Address: J C PATENTS, 4 VENTURE, SUITE 250, IRVINE, CA, 92618, US

(73) Assignee: HITACHI HIGH-TECHNOLOGIES CORPORATION, TOKYO (JP)

(21) Appl. No.: 12/540,858

(22) Filed: Aug. 13, 2009

(30) Foreign Application Priority Data
Aug. 18, 2008 (JP) 2008-209782

(51) Int. Cl. G03F 7/20; G03B 27/58

(52) U.S. Cl. 430/30; 355/72

(57) ABSTRACT

A range of a coordinate of drawing data supplied to a digital micromirror device (DMD) driving circuit 27 of a light beam irradiation device 20 is determined to configure a bandwidth of a light beam irradiated from an irradiation optical system of the light beam irradiation device 20. The drawing data having the determined range of the coordinate is supplied to the DMD driving circuit 27 of the light beam irradiation device 20. Movement of a stage 7 is controlled to move a chuck 10 for only a distance less than the bandwidth of the light beam irradiated from the irradiation optical system of the light beam irradiation device 20 towards a direction perpendicular to a scanning direction of the substrate by the light beam of the light beam irradiation device 20, at each scanning, and a same region of the substrate is scanned multiple times.

### CROSS-REFERENCE TO RELATED APPLICATION

This application claims the priority of Japanese application serial no. 2008-209782, filed Aug. 18, 2008. All disclosure of the Japanese application is incorporated herein by reference.

### BACKGROUND OF THE INVENTION

1. Field of the Invention

The present invention is related to an exposure apparatus, an exposure method, and a method of manufacturing a display panel substrate which adopts the foregoing exposure apparatus and method, wherein the exposure apparatus and the exposure method are used for emitting a light beam to irradiate a substrate coated with a photoresist and scanning the substrate with the light beam to draw a pattern on the substrate in the manufacturing of the display panel substrates of liquid crystal display devices. In particular, the present invention is related to an exposure apparatus and an exposure method which involve scanning a substrate by a plurality of light beams, and is related to a method of manufacturing a display panel substrate which adopts the exposure apparatus and the exposure method.

2. Description of Related Art

Thin film transistor (TFT) substrates, color filter substrates, plasma display panel substrates, or electroluminescence (EL) display panel substrates used as display panels of liquid crystal display devices are manufactured by performing photolithography technologies to form patterns on substrates with use of exposure apparatuses. The following methods have been used in conventional exposure apparatuses: a projection method in which a pattern of a photomask (mask) pattern is projected on a substrate by using lenses or mirrors, a proximity method in which extremely small gaps (proximity gaps) are disposed between the mask and the substrate for transferring the pattern of the mask onto the substrate.

In recent years, a kind of exposure apparatus as described below has been developed. In the exposure apparatus, a substrate having a photoresist coated thereon is irradiated by a light beam and scanned by the light beam, and patterns are drawn on the substrate. Since the substrate is scanned by the light beam, and the patterns are directly drawn on the substrate, there is no requirement for expensive masks. In addition, drawing data and scanning programs can be varied for adaptation to various sorts of display panel substrates. This kind of exposure apparatuses are, for example, disclosed in Japanese Patent Publication Number 2003-332221, Japanese Patent Publication Number 2005-353927, and Japanese Patent Publication Number 2007-219011.

The scanning of substrate by the light beams is performed by moving the substrate relative to the light beams. Generally, light beam irradiation devices which include precise optical systems are fixed in certain positions, and a stage is used to move a chuck supporting the substrate. FIGS. 11˜14 illustrate scanning a substrate with light beams. FIGS. 11˜14 illustrate using eight light beam irradiation devices and scanning the entire substrate 1 four times in an X direction by using eight light beams from the eight light beam irradiation device. Each of the light beam irradiation devices includes a head 20a having the irradiation optical system for irradiating the substrate with the light beam. Referring to FIGS. 11˜14, the head of each of the light beam irradiation device is represented by dotted lines. A light beam irradiated from the head 20a of each of the light beam irradiation devices has a bandwidth W in a Y direction and scans the substrate 1 towards a direction indicated by the arrow through movement of the stage towards the X direction.

FIG. 11 illustrates the first time of scanning in the X direction to draw patterns in a scan region highlighted with gray in FIG. 11. After the first scanning, through movement of the stage towards the Y direction, the substrate 1 moves towards the Y direction only for a distance the same as the bandwidth W. FIG. 12 illustrates the second time of scanning in the X direction to draw patterns in the scan region highlighted with gray in FIG. 12. After the second scanning, through movement of the stage towards the Y direction, the substrate 1 moves towards the Y direction only for a distance the same as the bandwidth W. FIG. 13 illustrates the third time of scanning in the X direction to draw patterns in the scan region highlighted with gray in FIG. 13. After the third scanning, through the movement of the stage towards the Y direction, the substrate 1 moves towards the Y direction only for a distance the same as the bandwidth W. FIG. 14 illustrates the third time of scanning in the X direction to draw patterns in the scan region highlighted with gray in FIG. 14, thereby completing scanning of the entire substrate 1.

As described above, under circumstances of scanning the substrate multiple times by using the light beam, the photoresist on the substrate is hardened, and the hardening of the photoresist caused by irradiation of the light beam occurs at certain time interval during each scanning, so that there are borderlines of the scan regions on the drawn patterns. In semiconductor integrated circuit substrates or print substrates, even if there are borderlines in circuit patterns, as long as the circuit patterns are electrically connected, no problems occur. However, in display panel substrates of liquid crystal display devices, if there are borderlines in the patterns, the borderlines are visible to the human eye, which causes problems of decreased definition.

### SUMMARY OF THE INVENTION

The present invention is directed to inhibiting or preventing formation of borderlines of scan regions on patterns when scanning a substrate multiple times and forming the patterns on the substrate.

The present invention is further directed to making the borderlines of the scan regions formed on the patterns hard to be recognized by the human eye when the light beam is used to scan the substrate multiple times to draw the patterns on the substrate.

The present invention is further directed to manufacturing display panel substrates having high quality.

A characteristic of the present invention is an exposure apparatus or an exposure method, wherein a chuck supports a substrate coated with a photoresist. The chuck is moved by using a stage. The substrate is scanned multiple times by light beams irradiated from a plurality of light beam irradiation devices to draw patterns on the substrate. The light beam irradiation device has a spatial light modulator which modulates the light beam, a driving circuit which drives the spatial light modulator according to drawing data, and an irradiation optical system which emits the light beam modulated by the spatial light modulator. A characteristic of the exposure apparatus or the exposure method is that a range of a coordinate of the drawing data supplied to the driving circuit of the light irradiation device is determined to configure the bandwidth of the light beam irradiated from the irradiation optical system of the light beam irradiation device, the drawing data having the determined range of the coordinate is supplied to the driving circuit of the light beam irradiation device, movement of the stage is controlled to move the chuck for a distance less than the bandwidth of the light beam irradiated from the irradiation optical system of the light beam irradiation device towards a direction perpendicular to the scanning direction of the substrate by the light beam from the light beam irradiation device at each scanning, and the same region of the substrate is repeatedly scanned.

The spatial light modulator of the light beam irradiation device is formed by arranging a plurality of light-reflecting micro mirrors along two directions, and angles of the mirrors are varied by the driving circuit according to the drawing data, so as to modulate the light beam irradiating the substrate. The light beam modulated by the spatial light modulator is irradiated from a head of the irradiation optical system of the light beam irradiation device to the substrate supported by the chuck. The range of the coordinate of the drawing data supplied to the driving circuit of the light beam irradiation device is determined to configure the bandwidth of the light beam irradiated from the irradiation optical system of the light beam irradiation device. The drawing data having the determined range of the coordinate is provided to the driving circuit of the light beam irradiation device. Afterwards, movement of the stage is controlled to move the chuck for only a distance less than the bandwidth of the light beam irradiated from the irradiation optical system of the light beam irradiation device towards a direction perpendicular to the scanning direction of the substrate by the light beam from the light beam irradiation device at each scanning, and the same region of the substrate is repeatedly scanned. Therefore, parts of the scan regions overlap at each scanning, so that the borderlines of the scan regions are indistinct, thereby inhibiting the formation of the borderlines of the scan regions on the patterns.

Moreover, if the same region of the substrate is repeatedly scanned multiple times, a scanning time increases, but at each scanning, the amount of light beam irradiating the photoresist on the substrate may be insignificant. Therefore, when the same region of the substrate is repeated scanned multiple times, the scanning speed is faster than scanning each of the regions of the substrate only once, and increases in tact time are prevented.

Another characteristic of the present invention is that at each scanning, the chuck is moved for a distance equal to a pitch of pixel formed on the substrate or equal to a multiple of the pitch towards a direction perpendicular to the scanning direction of the substrate by the light beam from the light beam irradiation device. At each scanning, the chuck is moved for a distance equal to the pitch of pixel formed on the substrate or equal to a multiple of the pitch towards a direction perpendicular to the scanning direction of the substrate by the light beam from the light beam irradiation device. When black matrix patterns are drawn on color filters substrates used in display panel substrates of liquid crystal display device, the borderlines of the scan regions may exist on positions of pixels where fewer black matrix patterns are located. Hence, even if the borderlines of the scan regions are formed on the patterns, the borderlines are still hard to be recognized by the human eye.

Another characteristic of the present invention is an exposure apparatus or an exposure method, wherein a chuck supports a substrate coated with a photoresist. The chuck is moved by using a stage. A light beam from a light beam irradiation device as described below scans the substrate multiple times to draw patterns on the substrate. The light beam irradiation device has a spatial light modulator which modulates the light beam, a driving circuit which drives the spatial light modulator according to drawing data, and an irradiation optical system which emits the light beam modulated by the spatial light modulator. A characteristic of the exposure apparatus or the exposure method is that a range of coordinate of the drawing data supplied to the driving circuit of the light irradiation device is determined to configure the bandwidth of the light beam irradiated from the irradiation optical system of the light beam irradiation device to be equal to a multiple of a pitch of pixel formed on the substrate, the drawing data having the determined range of the coordinate is provided to the driving circuit of the light beam irradiation device, movement of the stage is controlled to move the chuck for only a distance equal to the bandwidth of the light beam irradiated from the irradiation optical system of the light beam irradiation device towards a direction perpendicular to the scanning direction of the substrate by the light beam from the light beam irradiation device, at each scanning.

The bandwidth of the light beam irradiated from the irradiation optical system of the light beam irradiation device is configured to be equal to a multiple of the pitch of pixel formed on the substrate, movement of the stage is controlled to move the chuck only a distance equal to the bandwidth of the light beam irradiated from the irradiation optical system of the light beam irradiation device towards a direction perpendicular to the scanning direction of the substrate by the light beam from the light beam irradiation device at each scanning.

Another characteristic of the present invention is that a plurality of the light beam irradiation devices is disposed, and a plurality of the light beams from the light beam irradiation devices in parallel scans the substrate. The light beams from the light beam irradiation devices may be used to scan the substrate in parallel, so as to shorten the time required to scan the entire substrate, thereby shortening the tact time.

The exposure apparatus or the exposure method of the present invention may be used to expose the substrate, so as to inhibit or prevent the formation of the borderlines of the scan regions on the patterns, and thereby display panel substrates having high quality can be formed.

In order to make the aforementioned and other features and advantages of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic view of an exposure apparatus according to an embodiment of the present invention.

FIG. 2 is a lateral view of an exposure apparatus according to an embodiment of the present invention.

FIG. 3 is a front view of an exposure apparatus according to an embodiment of the present invention.

FIG. 4 is a schematic view of a light beam irradiation device.

FIG. 5 is a schematic view of a drawing controlling part.

FIG. 6 is a schematic view showing an exposure method according to an embodiment of the present invention.

FIG. 7 is a schematic view showing an exposure method according to another embodiment of the present invention.

FIG. 8 is a schematic view showing an exposure method according to still another embodiment of the present invention.

FIG. 9 is a flowchart showing an exemplary process of fabricating a TFIT substrate of a liquid crystal display device.

FIG. 10 is a flowchart showing an exemplary process of fabricating a color filter substrate of a liquid crystal display device.

FIGS. 11˜14 illustrate scanning a substrate with light beams.

### DESCRIPTION OF EMBODIMENTS

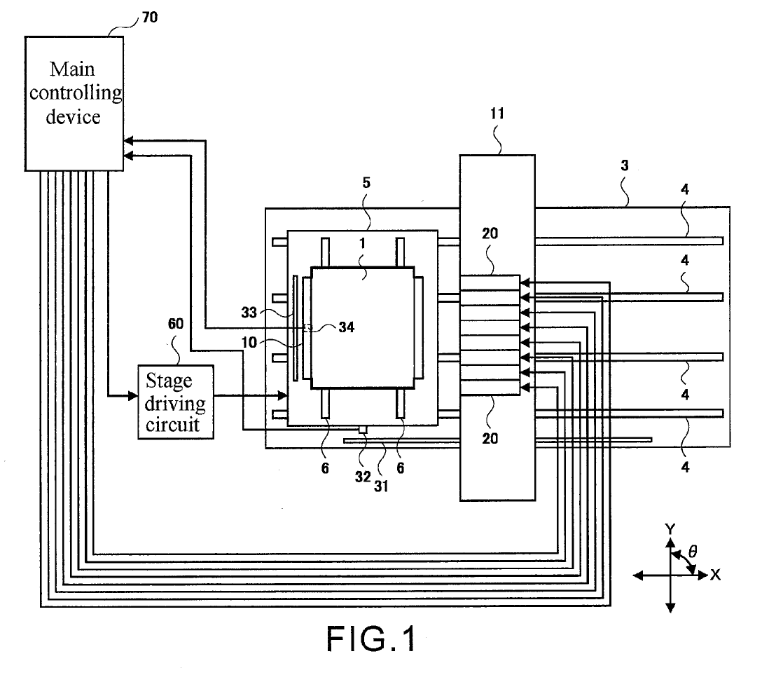

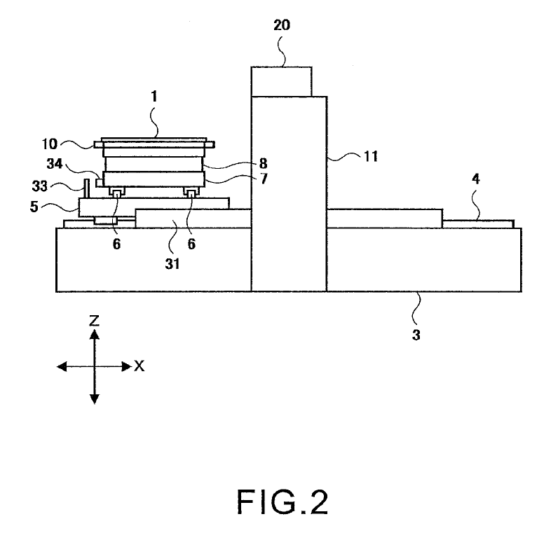

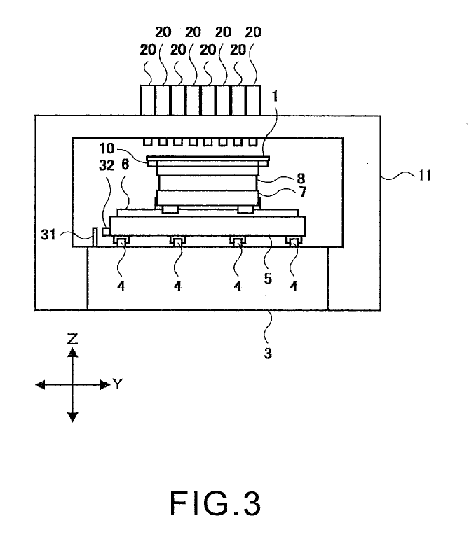

The following embodiments are described with reference to the examples shown in the enclosed figures. FIG. 1 is a schematic view of an exposure apparatus according to an embodiment of the present invention. In addition, FIG. 2 is a lateral view of the exposure apparatus according to an embodiment of the present invention, and FIG. 3 is a front view of the exposure apparatus according to an embodiment of the present invention. The exposure apparatus includes a base 3, an X-direction guide 4, an X-direction stage 5, a Y-direction guide 6, a Y-direction stage 7, a θ-direction stage 8, a chuck 10, a gate 11, light beam irradiation devices 20, linear scales 31 and 33, encoders 32 and 34, a stage driving circuit 60, and a main controlling device 70. It should be noted that the stage driving circuit 60 and the main controlling device 70 are omitted from FIG. 2 and FIG. 3. In addition to the above, the exposure apparatus further includes a supply unit for supplying a substrate 1 to the chuck 10, a retrieval unit for retrieving the substrate 1 from the chuck 10, and a temperature controlling unit for managing the temperature inside the apparatus.

The following embodiments are described with reference to the X and the Y directions, but it should be noted that the X direction and the Y direction can be varied.

As shown in FIG. 1 and FIG. 2, the chuck 10 is located in a supply-retrieval position for supplying and retrieving the substrate 1. In the aforesaid position, the substrate 1 is supplied to the chuck 10 by the supply unit (not shown) and retrieved from the chuck 10 by the retrieval unit (not shown). The chuck 10 supports a back side of the substrate 1 by vacuum suction. A surface of the substrate 1 is coated with a photoresist.

Above an exposure position where the substrate 1 is exposed, the gate 11 is disposed across the base 3. The gate 11 carries a plurality of light beam irradiation devices 20 thereon. In addition, although the exposure apparatus described in the present embodiment has only eight light beam irradiation devices 20, the present invention is not limited thereto. Within the spirit and scope of the present invention, the exposure apparatus can include seven or less than seven light beam irradiation devices or nine or more than nine light beam irradiation devices.

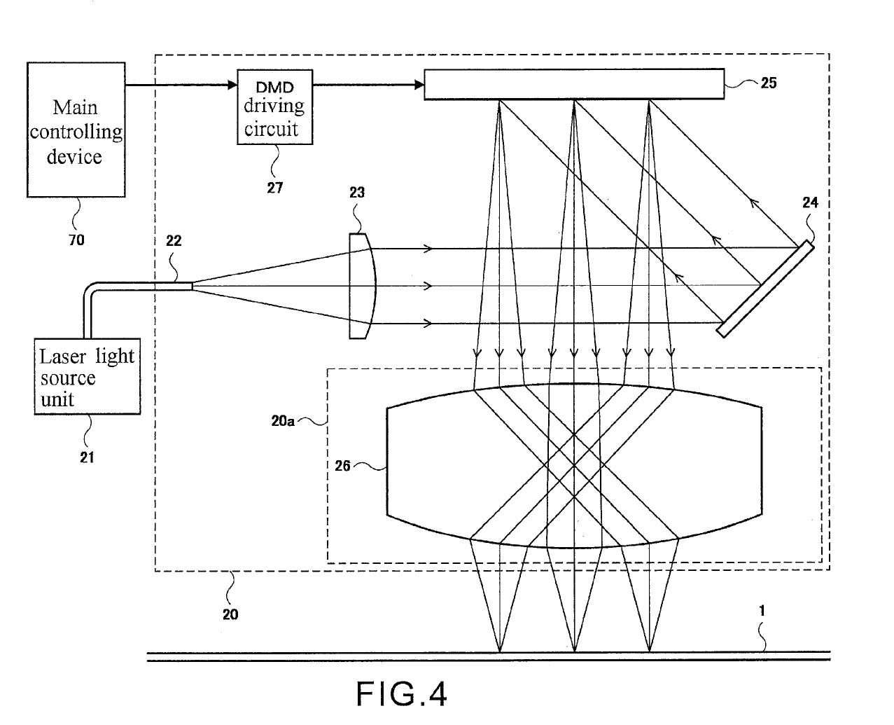

FIG. 4 is a schematic view of a light beam irradiation device. Each of the light beam irradiation devices 20 includes an optical fiber 22, a lens 23, a mirror 24, a digital micro mirror device (DMD) 25, a projection lens 26, and a DMD driving circuit 27. The optical fiber 22 guides an ultraviolet light beam which is generated by the laser source unit 21 into the light beam irradiation device 20. The light beam emitted from the optical fiber 22 irradiates the DMD 25 through the lens 23 and the mirror 24. The DMD 25 is a spatial light modulator formed by arranging a plurality of light-reflecting micro mirrors along two directions, and angles of the mirrors are varied so as to modulate the light beam. The light beam modulated by the DMD 25 is irradiated from a head 20a which contains the projection lens 26. The DMD driving circuit 27 varies the angle of each of the mirrors based on drawing data provided by the main controlling device 70.

Referring to FIG. 2 and FIG. 3, the chuck 10 is disposed on the θ-direction stage 8, and the Y-direction stage 7 and the X-direction stage 5 are disposed under the θ-direction stage 8. The X-direction stage 5 is installed on the X-direction guide 4 which is disposed on the base 3 and the X-direction stage 5 moves towards the X direction along the X-direction guide 4. The Y-direction stage 7 is installed on the Y-direction guide 6 which is disposed on the X-direction stage 5, and the Y-direction stage 7 moves towards the Y direction along the Y-direction guide 6. The θ-direction stage 8 is disposed on the Y-direction stage 7 and rotates towards a θ direction.

As the θ-direction stage 8 rotates towards the θ direction, the substrate 1 fixed on the chuck 10 is rotated in a way that two perpendicular sides of the substrate 1 respectively face the X direction and the Y direction. As the X-direction stage 5 moves towards the X direction, the chuck 10 shifts between the supply-retrieval position and the exposure position. At the exposure position, the light beam irradiated from the head 20a of each of the light beam irradiation devices 20 scans the substrate 1 along the X direction as the X-direction stage 5 moves towards the X direction. Moreover, a region of the substrate 1, which is scanned by the light beam from the head 20a of each of the light beam irradiation devices 20, moves towards the Y direction as the Y-direction stage 7 moves towards the Y direction. Referring to FIG. 1, the stage driving circuit 60 is controlled by the main controlling device 70, so as to rotate the θ-direction stage 8 towards the θ direction, to move the X-direction stage 5 towards the X direction, and to move the Y-direction stage 7 towards the Y direction.

In FIG. 1 and FIG. 2, the linear scale 31 which extends towards the X direction is disposed on the base 3. The linear scale 31 has graduations thereon for measuring a movement of the X-direction stage 5 towards the X direction. Moreover, the linear scale 33 which extends towards the Y direction is disposed on the X-direction stage 5. The linear scale 33 also has graduations thereon for measuring a movement of the Y-direction stage 7 towards the Y direction.

Referring to FIG. 1 and FIG. 3, on one side of the X-direction stage 5, the encoder 32 is disposed opposite to the linear scale 31. The encoder 32 detects the graduations of the linear scale 31 and outputs pulse signals to the main controlling device 70. Further, referring to FIG. 1 and FIG. 2, on one side of the Y-direction stage 7, the encoder 34 is disposed opposite to the linear scale 33. The encoder 34 detects the graduations of the linear scale 33 and outputs pulse signals to the main controlling device 70. The main controlling device 70 counts the pulse signals from the encoder 32 to calculate the movement of the X-direction stage 5 towards the X direction and counts the pulse signals from the encoder 34 to calculate the movement of the Y-direction stage 7 towards the Y direction.

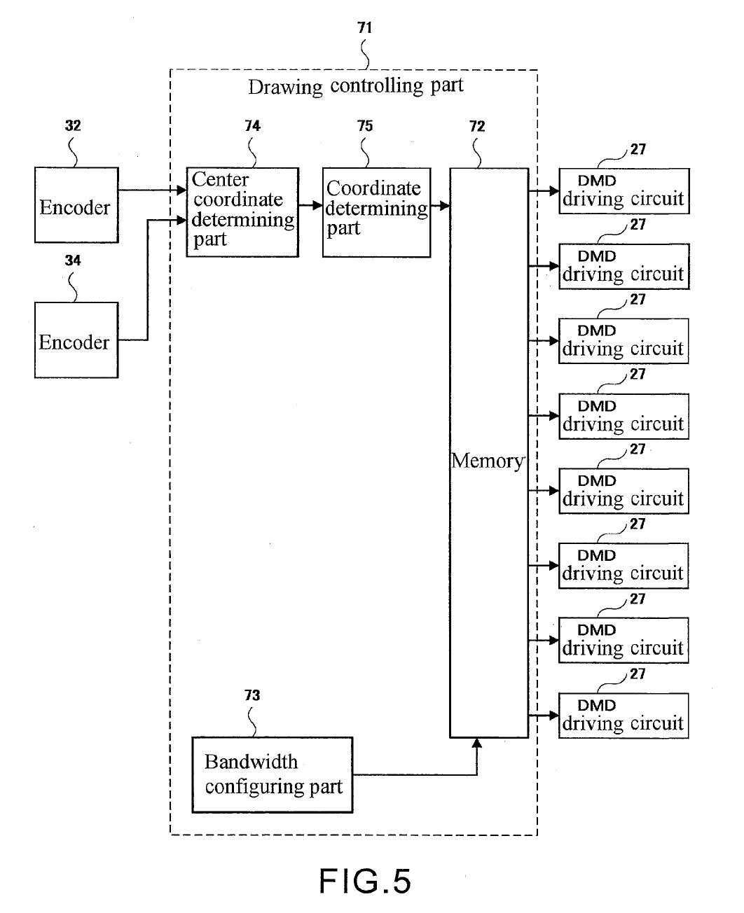

With reference to FIG. 1, the main controlling device 70 includes a drawing controlling part for supplying the drawing data to the DMD driving circuit of the light beam irradiation device 20. FIG. 5 is a schematic view of the drawing controlling part. The drawing controlling part 71 includes a memory 72, a bandwidth configuring part 73, a center coordinate determining part 74, and a coordinate determining part 75. The memory 72 records the XY coordinate of the drawing data as an address. Here, the drawing data is supplied to the DMD driving circuit 27 of each light beam irradiation device 20.

The bandwidth configuring part 73 determines a range of the Y coordinate of the drawing data read from the memory 72, and thereby a bandwidth of the light beam irradiated from the head 20a of the light beam irradiation device 20 in the Y direction is configured.

The center coordinate determining part 74 counts the pulse signals from the encoders 32 and 34, so as to detect and measure the movement of the X-direction stage 5 towards the X direction and the movement of the Y-direction stage 7 towards the Y direction, and thereby the XY coordinate of a center of the chuck 10 is determined.

The coordinate determining part 75 determines the XY coordinate of the drawing data that is supplied to the DMD driving circuit 27 of each light beam irradiation device 20 based on the XY coordinate of the center of the chuck 10 that is determined by the center coordinate determining part 74. The memory 72 inputs the XY coordinate determined by the coordinate determining part 75 as an address and outputs the drawing data recorded in the address of the inputted XY coordinate to the DMD driving circuit 27 of each light beam irradiation device 20.

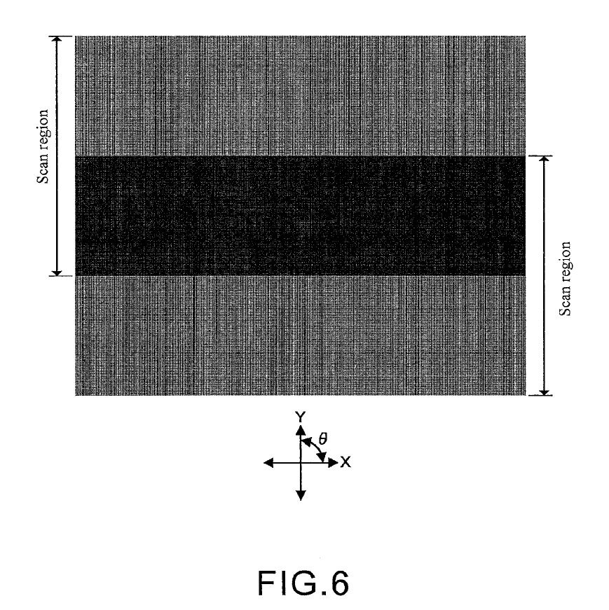

The exposure method of the present invention is described below. FIG. 6 is a schematic view showing an exposure method according to an embodiment of the present invention. According to the present embodiment, the movement of the Y-direction stage 7 is controlled to move the chuck 10 for only a distance less than the bandwidth of the light beam irradiated from the head 20a of the light beam irradiation device 20 in the direction (the Y direction) perpendicular to the scanning direction of the substrate 1 (the X direction) by the light beam from the light beam irradiation device 20 at each scanning, and the same region of the substrate 1 is scanned multiple times.

Referring to FIG. 1, the main controlling device 70 controls the stage driving circuit 60, so that the X-direction stage 5 moves towards the X direction, and the light beam from each light beam irradiation device 20 is used to perform the first scanning on the substrate towards the X direction. After the first scanning towards the X direction, the main controlling device 70 controls the stage driving circuit 60, so that the Y-direction stage 7 moves towards the Y direction, and that the chuck 10 is moved for only a distance less than the bandwidth of the light beam irradiated from the head 20a of the light beam irradiation device 20 in the direction (the Y direction) perpendicular to the scanning direction of the substrate 1 (the X direction) by the light beam from the light beam irradiation device 20. Afterwards, the main controlling device 70 controls the stage driving circuit 60, so that the X-direction stage 5 moves towards the X direction, and the light beam from each light beam irradiation device 20 is used to perform the second scanning on the substrate 1 towards the X direction. Then, the above step is performed repeatedly, so that the entire substrate 1 is scanned.

FIG. 6 shows the scan region on which the second scanning is performed, wherein parts of the scan regions represented by grey at each scanning overlap, so that the borderlines of the scan regions are indistinct, thereby inhibiting formation of borderlines of the scan regions on the patterns. In addition, according to the embodiment shown in FIG. 6, at each scanning, the chuck 10 is moved for only a distance equal to half of the bandwidth of the light beam irradiated from the head 20a of the light beam irradiation device 20, but the present invention is not limited thereto. Alternatively, parts of the scan regions overlap at each scanning, and the chuck 10 is moved for only a distance less than the bandwidth of the light beam irradiated from the head 20a of each light beam irradiation device 20 at each scanning.

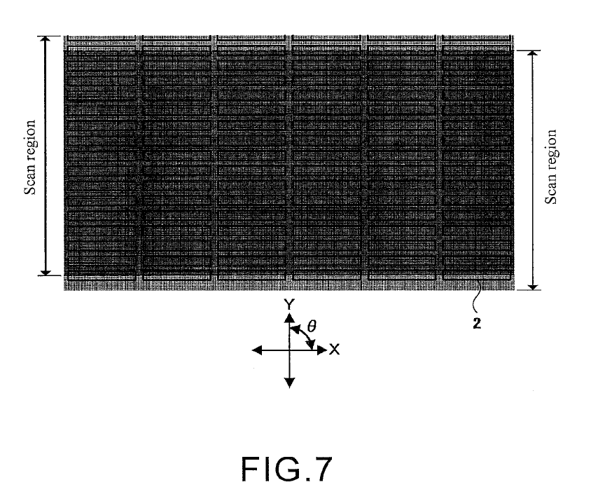

FIG. 7 is a schematic view showing an exposure method according to another embodiment of the present invention. According to the present embodiment, at each scanning, the chuck 10 is moved for a distance equal to a pitch of pixel 2 formed on the substrate 1 or equal to a multiple of the pitch towards a direction (the Y direction) perpendicular to the scanning direction of the substrate 1 (the X direction) by the light beam from the light beam irradiation device 20.

When black matrix patterns are drawn on color filter substrates used in display panel substrates of liquid crystal display devices, as shown in FIG. 1, the main controlling device 70 controls the stage driving circuit 60, so that the X-direction stage 5 moves towards the X direction, and the light beam from each light beam irradiation device 20 is used to perform the first scanning on the substrate 1 towards the X direction. After the first scanning towards the X direction, the main controlling device 70 controls the stage driving circuit 60, so that the Y-direction stage 7 moves towards the Y direction, and the chuck 10 is moved for only a distance equal to the pitch of pixel formed on the substrate 1 or equal to a multiple of the pitch in the direction (the Y direction) perpendicular to the scanning direction of the substrate 1 (the X direction) by the light beam from the light beam irradiation device 20. Afterwards, the main controlling device 70 controls the stage driving circuit 60, so that the X-direction stage 5 moves towards the X direction, and the light beam from each light beam irradiation device 20 is used to perform the second scanning on the substrate 1 towards the X direction. Then, the above step is performed repeatedly, so that the entire substrate 1 is scanned.

FIG. 7 shows the scan region on which the second scanning is performed. Since the borderlines of each of the scan regions indicated by dotted lines may exist at positions of the pixels where fewer black matrix patterns are formed, even if the borderlines of the scan regions may exist on the patterns, the borderlines are hard to be recognized by the human eye. In addition, according to the embodiment shown in FIG. 7, at each scanning, the chuck 10 is moved for only a distance equal to the pitch of pixel 2 formed on the substrate 1, but the present invention is not limited thereto. The chuck 10 may also be moved for only a distance equal to a multiple of the pitch of pixel 2 formed on the substrate 1.

According to the embodiments shown in FIG. 6 and FIG. 7, the movement of the Y-direction stage 7 is controlled at each scanning, and the chuck 10 is moved for only a distance less than the bandwidth of the light beam irradiated from the head 20a of each light beam irradiation device 20 in the direction (the Y direction) perpendicular to the scanning direction of the substrate 1 (the X direction) by the light beam from the light beam irradiation device 20. The same region of the substrate 1 is scanned multiple times, such that parts of the scan regions overlap at each scanning, the borderlines of the scan regions are indistinct, and formation of the borderlines of the scan regions on the patterns is inhibited.

According to the embodiment shown in FIG. 7, at each scanning, the chuck 10 is moved for a distance equal to the pitch of pixel 2 formed on the substrate 1 or equal to a multiple of the pitch towards a direction (the Y direction) perpendicular to the scanning direction of the substrate 1 (the X direction) by the light beam from each light beam irradiation device 20, so that when black matrix patterns are drawn on color filters substrates used in display panel substrates of liquid crystal display devices, the borderlines of the scan regions may exist on positions of pixels where fewer black matrix patterns are located. Hence, even if the borderlines of the scan regions are formed on the patterns, the borderlines are still hard to be recognized by the human eye.

Moreover, if the same region of the substrate 1 is repeatedly scanned multiple times, a scanning time increases, but at each scanning, the amount of light beam irradiating the photoresist on the substrate 1 may be insignificant. Therefore, when the same region of the substrate is repeated scanned multiple times, the scanning speed is faster than scanning each of the regions of the substrate only once, and increases in tact time are prevented.

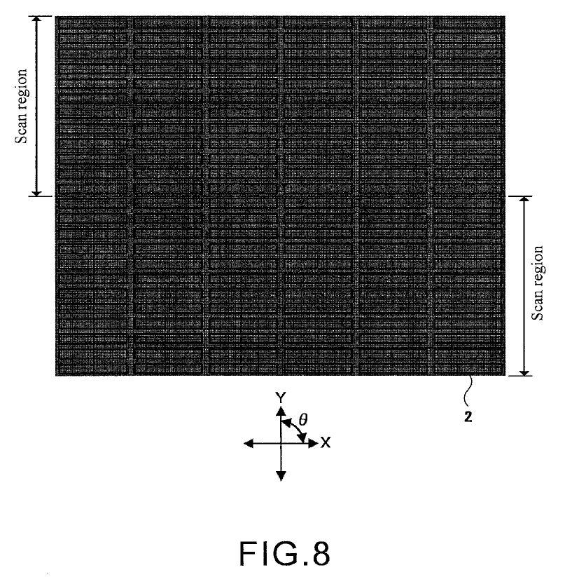

FIG. 8 is a schematic view showing an exposure method according to still another embodiment of the present invention. According to the present embodiment, the bandwidth of the light beam irradiated from the head 20a of each light beam irradiation device 20 is configured to be equal to a multiple of the pitch of pixel 2 formed on the substrate 1, the movement of the Y-direction stage 7 is controlled at each scanning, and the chuck 10 is moved for only a distance equal to the bandwidth of the light beam irradiated from the head 20a of each light beam irradiation device 20 towards the direction (the Y direction) perpendicular to the scanning direction of the substrate 1 (the X direction) by the light beam of the light beam irradiation device 20.

When the color patterns are drawn on the color filter substrates used in display panel substrates of liquid crystal display devices, referring to FIG. 5, the bandwidth configuring part 73 of the drawing controlling part 71 determines a range of the Y coordinate of the drawing data read from the memory 72, and thereby the bandwidth of the light beam irradiated from the head 20a of each light beam irradiation device 20 in the Y direction is configured to be equal to a multiple of the pitch of pixel 2 formed on the substrate 1. Referring to FIG. 1, the main controlling device 70 controls the stage driving circuit 60, so that the X-direction stage 5 moves towards the X direction, and the light beam from each light beam irradiation device 20 is used to perform the first scanning on the substrate 1 towards the X direction. After the first scanning towards the X direction, the main controlling device 70 controls the stage driving circuit 60, so that the Y-direction stage 7 moves towards the Y direction, and the chuck 10 is moved for only a distance equal to the bandwidth of the light beam irradiated from the head 20a of each light beam irradiation device 20 in the direction (the Y direction) perpendicular to the scanning direction of the substrate 1 (the X direction) by the light beam from the light beam irradiation device 20. Afterwards, the main controlling device 70 controls the stage driving circuit 60, so that the X-direction stage 5 moves towards the X direction, and the second scanning is performed on the substrate 1 towards the X direction by using the light beam from each light beam irradiation device 20. Then, the above step is performed repeatedly, so that the entire substrate 1 is scanned.

FIG. 8 shows the scan region on which the second scanning is performed. The borderlines of each of the scan regions indicated by dotted lines may be absent from the positions of the black matrixes of the drawn color patterns, so that formation of the borderlines of the scan regions on the patterns is prevented.

According to the embodiment shown in FIG. 8, the bandwidth of the light beam irradiated from the head 20a of each light beam irradiation device 20 is configured to be equal to a multiple of the pitch of pixel 2 formed on the substrate 1, the movement of the Y-direction stage 5 is controlled at each scanning, and the chuck 10 is moved for only a distance equal to the bandwidth of the light beam irradiated from the head 20a of each light beam irradiation device 20 in the direction (the Y direction) perpendicular to the scanning direction of the substrate 1 (the X direction) by the light beam of the light beam irradiation device 20. Hence, when the color patterns are drawn on the color filter substrates used in display panel substrates, the borderlines of the scan regions may be absent from the positions of the black matrixes of the drawn color patterns, so that formation of the borderlines of the scan regions on the patterns is prevented.

According to the embodiments described above, the substrate 1 can be scanned in parallel by a plurality of light beams from the light beam irradiation devices 20, so as to shorten the time required to scan the entire substrate 1, thereby shorting the tact time.

The exposure apparatus or the exposure method of the present invention can be applied to the exposure of the substrate, so as to inhibit or prevent the formation of the borderlines of the scan regions, and thereby display panel substrates having high quality can be formed.

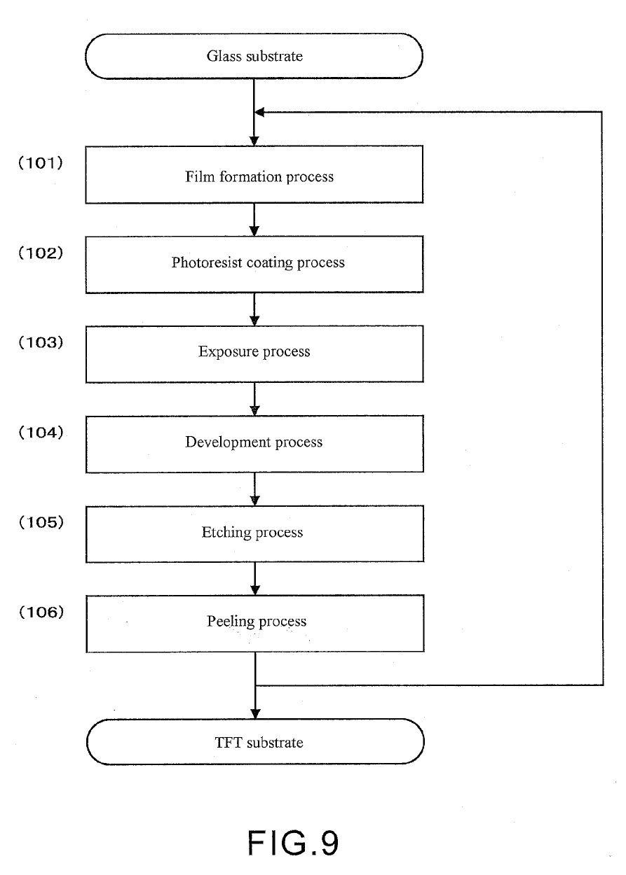

FIG. 9 is a flowchart showing an exemplary process of fabricating a TFT substrate of a liquid crystal display device. In a film formation process, (Step 101), a thin film such as a conductive film which serves as a transparent electrode for driving liquid crystals or an insulating film is formed on the substrate by using a sputtering method or a chemical vapor deposition (CVD) method. In a photoresist coating process (Step 102), the photoresist is applied by a roll coating method so as to form a photoresist film on the thin film which is formed in the film formation process (Step 101). In an exposure process (Step 103), a pattern is formed in the photoresist film by using the exposure apparatus. In a development process (Step 104), a development solution is applied onto the photoresist film, so as to remove an unnecessary portion of the photoresist film by using a method such as a shower development method. In an etching process (Step 105), a portion, which is not masked by the photoresist film, of the thin film formed in the film formation process (Step 101) is removed by a wet etching method. In a peeling process (Step 106), the photoresist film which functions as a mask in the etching process (Step 105) is peeled by using a peeling solution. It should be noted that some cleaning or drying processes need to be performed on the substrate before or after each of the aforementioned processes. After the aforementioned processes are repeated for several times, a TFT array is formed on the substrate.

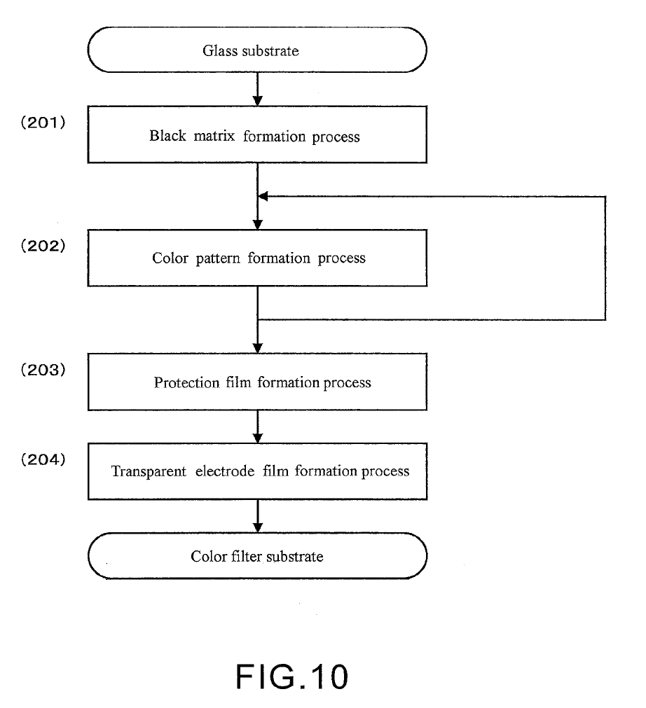

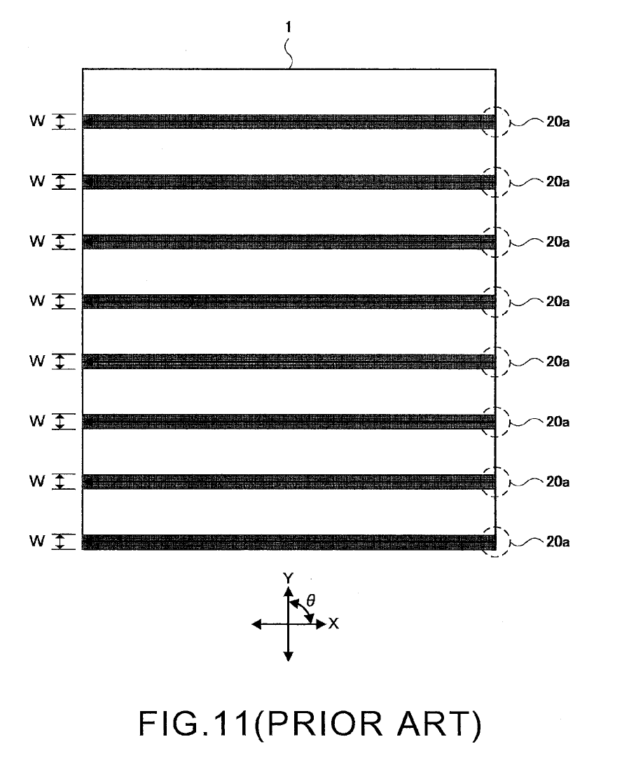

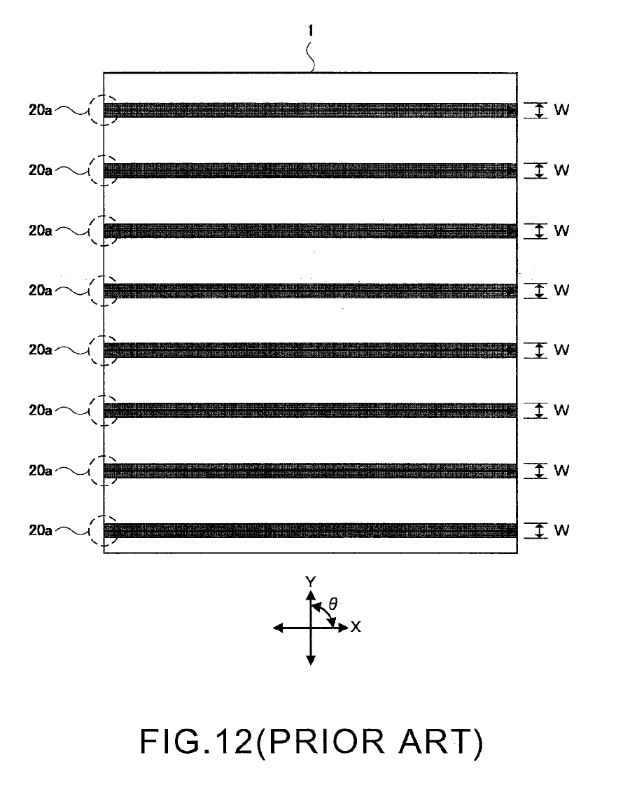

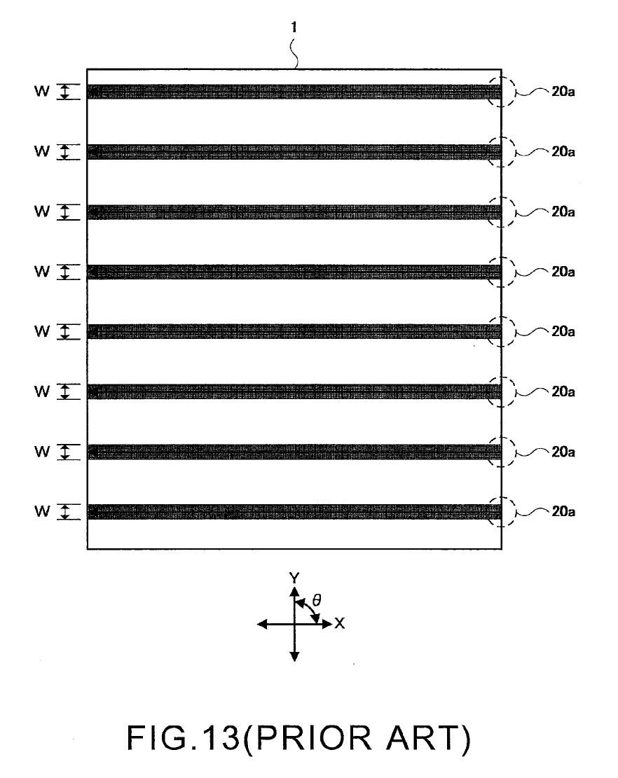

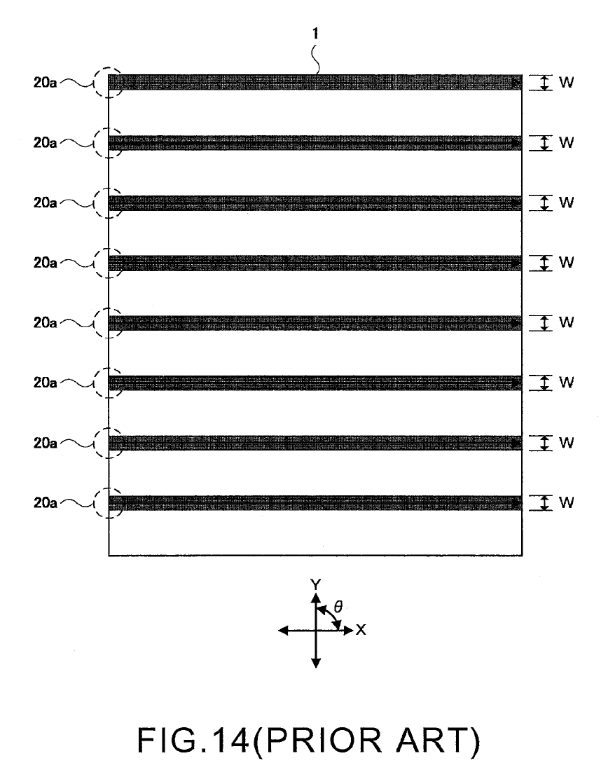

In addition, FIG. 10 is a flowchart showing an exemplary process of fabricating a color filter substrate of a liquid crystal display device. In a black matrix formation process (Step 201), the black matrix is formed on the substrate by the procedures such as photoresist coating, exposure, development, etching, peeling, and so forth. In a color pattern formation process (Step 202), the color pattern is formed on the substrate by using a method such as a printing method. This process can be repeated to form R, G and B color patterns. In a protection film formation process (Step 203), the protection film is formed on the color pattern. Further, in a transparent electrode film formation process (Step 204), the transparent electrode film is formed on the protection film. It should be noted that cleaning or drying processes may need to be performed on the substrate before or during or after each of the aforementioned processes.

In the process of fabricating the color filter substrate shown in FIG. 10, the exposure apparatus or the exposure method of the present invention can be used for exposure in the black matrix formation process (Step 201) and the color pattern formation process (Step 202) of fabricating the color filter substrate.

Although the present invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. An exposure apparatus, comprising:
a chuck supporting a substrate coated with a photoresist;
a stage moving the chuck; and
a light beam irradiation device comprising a spatial light modulator modulating a light beam, a driving circuit driving the spatial light modulator according to drawing data, and an irradiation optical system emitting the light beam modulated by the spatial light modulator,
wherein the stage moves the chuck, the substrate is scanned multiple times by a light beam irradiated from the light beam irradiation device to draw patterns on the substrate, the exposure apparatus being characterized by:
a drawing controlling means determining a range of coordinates of the drawing data supplied to the driving circuit of the light beam irradiation device, configuring a bandwidth of the light beam irradiated from the irradiation optical system of the light beam irradiation device, and supplying the drawing data having the determined range of the coordinates to the driving circuit of the light beam irradiation device; and
a scanning controlling means controlling movement of the stage to move the chuck for a distance less than the bandwidth of the light beam irradiated from the irradiation optical system of the light beam irradiation device towards a direction perpendicular to a scanning direction of substrate by the light beam of the light beam irradiation device at each scanning,
wherein a same region of the substrate is scanned multiple times.

2. The exposure apparatus as claimed in claim 1, wherein at each scanning, the scanning controlling means moves the chuck for a distance equal to a pitch of pixel formed on the substrate or equal to a multiple of the pitch towards a direction perpendicular to a scanning direction of substrate by the light beam of the light beam irradiation device.

3. The exposure apparatus as claimed in claim 1, comprising a plurality of the light beam irradiation devices, wherein a plurality of the light beams irradiated from the light beam irradiation devices scan the substrate in parallel.

4. An exposure apparatus, comprising:
a chuck supporting a substrate coated with a photoresist;
a stage moving the chuck; and
a light beam irradiation device comprising a spatial light modulator modulating a light beam, a driving circuit driving the spatial light modulator according to drawing data, and an irradiation optical system emitting the light beam modulated by the spatial light modulator,
wherein the stage moves the chuck, the substrate is scanned multiple times by a light beam irradiated from the light beam irradiation device to draw patterns on the substrate, the exposure apparatus being characterized by:
a drawing controlling means determining a range of coordinates of the drawing data supplied to the driving circuit of the light beam irradiation device to configure a bandwidth of the light beam irradiated from the irradiation optical system of the light beam irradiation device as being equal to a multiple of a pitch of pixel formed on the substrate, and supplying the drawing data having the determined range of the coordinates to the driving circuit of the light beam irradiation device; and
a scanning controlling means controlling movement of the stage to move the chuck for a distance equal to the bandwidth of the light beam irradiated from the irradiation optical system of the light beam irradiation device towards a direction perpendicular to a scanning direction of substrate by the light beam of the light beam irradiation device scans the substrate at each scanning.

5. The exposure apparatus as claimed in claim 4, comprising a plurality of the light beam irradiation devices, wherein a plurality of the light beams irradiated from the light beam irradiation devices scan the substrate in parallel.

6. An exposure method, comprising:
supporting a substrate coated with a photoresist by a chuck;
moving the chuck by a stage;
scanning the substrate multiple times by using a light beam irradiated from a light beam irradiation device to draw patterns on the substrate, the light beam irradiation device comprising a spatial light modulator modulating the light beam, a driving circuit driving the spatial light modulator according to drawing data, and an irradiation optical system emitting the light beam modulated by the spatial light modulator, the exposure method being characterized by:
determining a range of coordinates of the drawing data supplied to the driving circuit of the light beam irradiation device to configure a bandwidth of the light beam irradiated from the irradiation optical system of the light beam irradiation device;
supplying the drawing data having the determined range of the coordinates to the driving circuit of the light beam irradiation device;
controlling movement of the stage to move the stage for a distance less than the bandwidth of the light beam irradiated from the irradiation optical system of the light beam irradiation device towards a direction perpendicular to a scanning direction of substrate by the light beam of the light beam irradiation device at each scanning; and
scanning a same region of the substrate multiple times.

7. The exposure method as claimed in claim 6, wherein, at each scanning, the chuck is moved for a distance equal to a pitch of pixel disposed on the substrate or equal to a multiple of the pitch.

8. The exposure method as claimed in claim 6, further comprising disposing a plurality of the light beam irradiation devices; and
scanning the substrate in parallel by using a plurality of the light beams from the light beam irradiation devices.

9. An exposure method, comprising:
supporting a substrate coated with a photoresist by a chuck;
moving the chuck by a stage;
scanning the substrate multiple times by using a light beam irradiated from a light beam irradiation device to draw patterns on the substrate, the light beam irradiation device comprising a spatial light modulator modulating the light beam, a driving circuit driving the spatial light modulator according to drawing data, and an irradiation optical system emitting the light beam modulated by the spatial light modulator, the exposure method being characterized by:
determining a range of coordinates of the drawing data supplied to the driving circuit of the light beam irradiation device to configure a bandwidth of the light beam irradiated from the irradiation optical system of the light beam irradiation device as being equal to a multiple of a pitch of pixel formed on the substrate;
supplying the drawing data having the determined range of the coordinates to the driving circuit of the light beam irradiation device; and
controlling movement of the stage to move the stage for a distance equal to the bandwidth of the light beam irradiated from the irradiation optical system of the light beam irradiation device towards a direction perpendicular to a scanning direction of substrate by the light beam of the light beam irradiation device, at each scanning.

10. The exposure method as claimed in claim 9, further comprising disposing a plurality of the light beam irradiation devices; and
scanning the substrate in parallel by using a plurality of the light beams from the light beam irradiation devices.

11. A method of manufacturing a display panel substrate, the method being characterized by adopting the exposure apparatus as claimed in claim 1 to expose a substrate.

12. A method of manufacturing a display panel substrate, the method being characterized by adopting the exposure apparatus as claimed in claim 4 to expose a substrate.

13. A method of manufacturing a display panel substrate, the method being characterized by adopting the exposure method as claimed in claim 6 to expose a substrate.

14. A method of manufacturing a display panel substrate, the method being characterized by adopting the exposure method as claimed in claim 9 to expose a substrate.
